(19) United States
(12) Patent Application Publication
(10) Pub. No.: US 2025/0244884 A1
(43) Pub. Date: Jul. 31, 2025

(54) STORAGE DEVICE

(71) Applicant: Samsung Electronics Co., Ltd., Suwon-si (KR)

(72) Inventors: Minwoo Son, Suwon-si (KR); Kyungduk Lee, Suwon-si (KR)

(21) Appl. No.: 18/802,249

(22) Filed: Aug. 13, 2024

(30) Foreign Application Priority Data
Jan. 25, 2024 (KR) 10-2024-0011412

(51) Int. Cl. G06F 3/06

(52) U.S. Cl. CPC G06F 3/0619; G06F 3/0659; G06F 3/0679

(57) ABSTRACT

A storage device includes: a non-volatile memory device comprising a plurality of memory blocks in which a plurality of cell strings are divided into a plurality of sub-blocks disposed in a vertical direction, wherein in each of the plurality of cell strings, a string select transistor, a plurality of memory cells and a ground select transistor are disposed in series, in the vertical direction, between a bit line and a source line; and a storage controller configured to program original data into at least one first sub-block of the plurality of sub-blocks in a first level cell mode, and program recovery data for recovering the original data into at least one second sub-block of the plurality of sub-blocks in a second level cell mode having a bit density greater than that of the first level cell mode, in a first memory block of the plurality of memory blocks.

### CROSS-REFERENCE TO RELATED APPLICATION(S)

This application claims benefit of priority under 35 U.S.C. § 119 to Korean Patent Application No. 10-2024-0011412 filed on Jan. 25, 2024, in the Korean Intellectual Property Office, the disclosure of which is incorporated herein by reference in its entirety.

### BACKGROUND

Aspect of the present inventive concept relate to a storage device.

Semiconductor memory devices for storing data can be broadly divided into volatile memory devices and non-volatile memory devices. A volatile memory device such as a dynamic random-access memory (DRAM) and the like, in which data is stored by charging or discharging a cell capacitor, maintains the stored data while power is applied thereto, whereas the stored data is lost when power is disconnected. Meanwhile, a non-volatile memory device can store data, even when power thereto is disconnected. A volatile memory device is mainly used as a main memory in a computer and the like, and a non-volatile memory device is used as a high-capacity memory to store programs and data in a wide range of application devices, such as computers, portable communication devices and the like.

Recently, in order to improve integration of semiconductor memory devices, non-volatile memory devices in which memory cells are three-dimensionally stacked, such as vertical NAND flash memory devices, are being actively researched.

### SUMMARY

An aspect of the present inventive concept is to provide a storage device having improved reliability by applying a vertical non-volatile memory device.

According to an aspect of the present inventive concept, a storage device includes: a non-volatile memory device comprising a plurality of memory blocks in which a plurality of cell strings are divided into a plurality of sub-blocks disposed in a vertical direction, wherein in each of the plurality of cell strings, a string select transistor, a plurality of memory cells and a ground select transistor are disposed in series, in the vertical direction, between a bit line and a source line; and a storage controller configured to program original data into at least one first sub-block of the plurality of sub-blocks in a first level cell mode, and program recovery data for recovering the original data into at least one second sub-block of the plurality of sub-blocks in a second level cell mode having a bit density greater than that of the first level cell mode, in a first memory block of the plurality of memory blocks.

According to an aspect of the present inventive concept, a storage device includes: a non-volatile memory device comprising a plurality of memory blocks including a plurality of cell strings which is divided into a first sub-block and a second sub-block disposed in a vertical direction to the first sub-block, and having a size smaller than that of the first sub-block, wherein in each of the plurality of cell strings, a string select transistor, a plurality of memory cells and a ground select transistor are disposed in series, in the vertical direction, between a bit line and a source line; and a storage controller configured to program original data into the first sub-block in a first level cell mode, and program mirrored data from which the original data is copied into the second sub-block in a second level cell mode having a bit density greater than that of the first level cell mode, in a first memory block of the plurality of memory blocks.

According to an aspect of the present inventive concept, a storage device includes: a non-volatile memory device comprising a plurality of memory blocks in which a plurality of cell strings are divided into a plurality of sub-blocks disposed in a vertical direction, wherein in each of the plurality of cell strings, a string select transistor, a plurality of memory cells and a ground select transistor are disposed in series, in the vertical direction, between a bit line and a source line; and a storage controller configured to program first original data into the plurality of sub-blocks in a first memory block of the plurality of memory blocks in a first level cell mode, program second original data into at least one first sub-block of the plurality of sub-blocks in a second memory block of the plurality of memory blocks in the first level cell mode, and program mirrored data from which the first original data and the second original data is copied into at least one second sub-block of the plurality of sub-blocks in the second memory block in a second level cell mode having a bit density greater than that of the first level cell mode.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a diagram illustrating a storage device according to an embodiment of the present inventive concept;

FIG. 2 is a diagram schematically illustrating a storage space of a storage device according to an embodiment of the present inventive concept;

FIG. 3 is an exemplary block diagram illustrating a non-volatile memory device;

FIG. 4 is an equivalent circuit diagram of a memory block formed in a vertical structure;

FIG. 5 is an exemplary block diagram illustrating a structure of a memory block;

FIGS. 6 to 8 are diagrams illustrating operations of a storage device according to an embodiment of the present inventive concept;

FIGS. 9 to 11 are diagrams illustrating operations of a storage device according to various embodiments of the present inventive concept;

FIG. 12 is a diagram illustrating an operation of a storage device according to an embodiment of the present inventive concept;

FIG. 13 is a flowchart illustrating a program operation of a storage device according to an embodiment of the present inventive concept;

FIGS. 14 and 15 are flowcharts illustrating a read operation of a storage device according to an embodiment of the present inventive concept;

FIGS. 16 and 17 are cross-sectional views illustrating a non-volatile memory device including sub-blocks; and

FIG. 18 is a diagram illustrating a system to which a storage device according to an embodiment of the present inventive concept may be applied.

### DETAILED DESCRIPTION

Hereinafter, exemplary embodiments of the present inventive concept will be described with reference to the accompanying drawings.

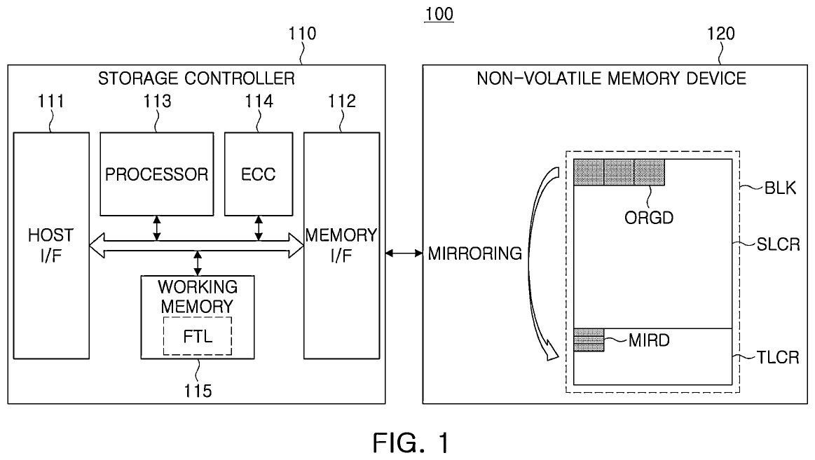

FIG. 1 is a diagram illustrating a storage device 100 according to an embodiment of the present inventive concept.

The storage device 100 may store data in response to a request from a host. For example, the storage device 100 may include at least one of a solid-state drive (SSD), an embedded memory and a removable external memory.

If the storage device 100 is an SSD, the storage device 100 may be a device in compliance with the non-volatile memory express (NVMe) standard. If the storage device 100 is an embedded memory or external memory, the storage device 100 may be a device that complies with the universal flash storage (UFS) or embedded multi-media card (eMMC) standard. The host and the storage device 100 may generate and transmit packets according to respective adopted standard protocol.

The storage device 100 may include a storage controller 110 and a non-volatile memory device 120. The non-volatile memory device 120 may be a storage medium that stores data received from the host, and may include, for example, flash memory. The storage controller 110 may control the non-volatile memory device 120.

The storage controller 110 may transmit/receive packets to/from the host. The packet transmitted from the host to the storage controller 110 may include a command, data to be written to the non-volatile memory device 120 or the like, and the packets transmitted from the storage controller 110 to the host may be a response to the command, data read out from the non-volatile memory device 120 or the like.

In addition, the storage controller 110 may transmit data to be written to the non-volatile memory device 120 to the non-volatile memory device 120, or receive data read out from the non-volatile memory device 120. The storage controller 110 may be implemented to transmit/receive data to/from the non-volatile memory device 120 in compliance with a standard protocol such as Toggle or Open NAND Flash Interface (ONFI).

When the non-volatile memory device 120 includes a flash memory, the flash memory may include a 3D (or vertical) NAND (VNAND) memory array. The vertical memory array may include a plurality of memory blocks including a plurality of cell strings, wherein in each cell string, a string select transistor, a plurality of memory cells and a ground select transistor are arranged in series in a vertical direction between a bit line and a source line.

In general, the non-volatile memory device 120 may be managed on a memory block basis. For example, the non-volatile memory device 120 may be erased on a memory block basis. Even if a portion of a memory block is defective, the entire memory block may be determined as a bad block, and use of the bad block may be prohibited.

Due to a high integration of the non-volatile memory device 120, a storage capacity of one memory block is increasing. Erasing the non-volatile memory device 120 on a memory block basis may make management of the non-volatile memory device 120 difficult. For example, whenever a defect occurs in a portion of a memory block and the entire memory block is determined as bad block, a capacity of the non-volatile memory device 120 may be significantly lost.

It has been proposed that the non-volatile memory device 120 divides a memory block into a plurality of sub-blocks and supports erasure on a sub-block basis. The plurality of cell strings included in the memory block of the non-volatile memory device 120 may be divided into a plurality of sub-blocks in the vertical direction. When the memory block can be erased on a sub-block basis, the sub-blocks included in the memory block may be individually treated as bad blocks, and the non-volatile memory device 120 may be managed on a sub-block basis. The storage controller 110 may generally control the non-volatile memory device 120.

The storage controller 110 may include a host interface 111, a memory interface 112, a processor 113, an error correction code (ECC) engine 114, and a buffer memory 115.

The host interface 111 can transmit/receive packets to/from the host. The packets transmitted from the host to the host interface 111 may include a command, data to be written to the non-volatile memory device 120 or the like, and the packets transmitted from the host interface 111 to the host may contain a response to the command, data read out from the non-volatile memory device 120 or the like.

The memory interface 112 may transmit data to be written to the non-volatile memory device 120 to the non-volatile memory device 120 or receive data read from the non-volatile memory device 120. This memory interface 112 may be implemented to comply with a standard protocol such as Toggle or Open NAND Flash Interface (ONFI).

The processor 113 may execute a flash translation layer (FTL). The FTL may be loaded into a working memory 115. Data writing and reading operations for the non-volatile memory device 120 may be controlled by the processor 113 executing the FTL.

The FTL may perform several functions such as address mapping and wear-leveling. The address mapping operation may be an operation that changes a logical address received from the host into a physical address used to actually store data in the non-volatile memory device 120. The wear-leveling operation may be a technology to prevent excessive deterioration of a specific memory block by ensuring that the memory blocks in the non-volatile memory device 120 are used uniformly, and for example, may be implemented through a firmware technology that balances erase counts of physical memory blocks.

The working memory 115 may store data required for an operation of the storage controller 110 and buffer data to be written to the non-volatile memory device 120 or data to be read from the non-volatile memory device 120. For example, the working memory 115 may include a volatile memory such as a static random-access memory (SRAM).

The ECC engine 114 may perform error detection and correction functions on read data read from the non-volatile memory device 120. For example, the ECC engine 114 may generate parity bits for write data to be written to the non-volatile memory device 120, and the parity bits may be programmed into the non-volatile memory device 120 along with the write data. When reading data from the non-volatile memory device 120, the ECC engine 114 may detect and correct an error in the read data using the parity bits read from the non-volatile memory device 120 along with the read data, and output the error-corrected read data.

The error correction performance of the ECC engine 114 may be limited. For example, the ECC engine 114 may become unable to correct errors in the read data if there are more than a certain number of errors in the read data and the parity bits. The inability to correct errors in certain data may be expressed as an occurrence of an uncorrectable ECC (UECC) in the data.

Despite the limitation in the error correction performance of the ECC engine 114, there may be methods by which the storage device 100 provides high reliability to data stored in the non-volatile memory device 120. For example, the storage device 100 may lower the possibility of a UECC occurring in the data by programming at least a portion of the data in a single level cell (SLC) mode in which a read error is less likely to occur.

In addition, the storage device 100 may further store recovery data required for recovery along with the original data to be stored in the non-volatile memory 120 so that the read data can be recovered even when a UECC occurs in the read data. For example, the non-volatile memory device 120 may store original data including write data and parity bits, and mirrored data copying the original data.

The mirrored data can be a powerful means of data recovery when a UECC occurs in the original data, but in order for the non-volatile memory device 120 to store the original data and the mirrored data together, a storage capacity of more than twice that of the original data may be required. Accordingly, it may be difficult to provide a sufficient storage capacity to a user of the storage device 100.

According to an embodiment of the present inventive concept, the storage device 100 provides strong recovery performance of original data stored in each memory block using memory blocks each including sub-blocks, while reducing a storage capacity required for storing recovery data in each memory block.

For example, the memory block BLK including the plurality of sub-blocks may be divided into a first region SLCR and a second region TLCR. The first region SLCR may include at least one first sub-block, and the at least one first sub-block may store data in a first level cell mode, for example, a single level cell (SLC) mode. The second region TLCR may include at least one second sub-block, and the at least one second sub-block may store data in a second level cell mode, for example, a triple level cell (TLC) mode.

The storage controller 110 may control the non-volatile memory device 120 in order to program original data ORGD into the first region SCLR of the memory block BLK in the first level cell mode, and program mirrored data MIRD generated by copying the original data ORGD into the second region TLCR in the second level cell mode. When the first level cell mode is the SLC mode and the second level cell mode is the TLC mode, the mirrored data MIRD may occupy a third of the storage space of the original data ORGD.

According to an embodiment of the present inventive concept, the storage device 100 may program original data ORGD into one memory block BLK in a first level cell mode, and program mirrored data MIRD in a second level of which bit density is greater than that of the first level, whereby it is possible to provide a recovery function for the original data when a UECC occurs in the original data, and to reduce a storage space for storing the recovery data. A bit density may refer to a number of data bits that can be stored in one memory cell.

In an embodiment, the storage device 100 may provide high reliability for metadata by using the memory block BLK as a meta-block for storing the metadata.

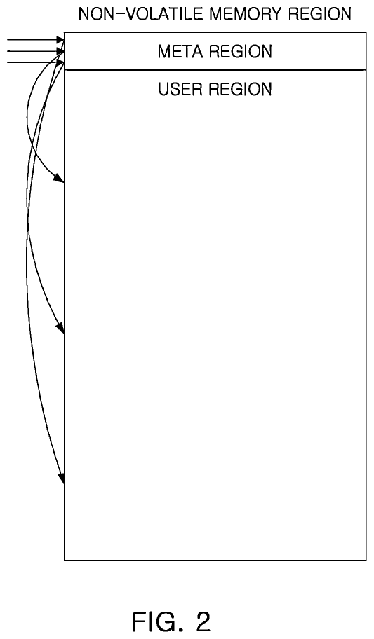

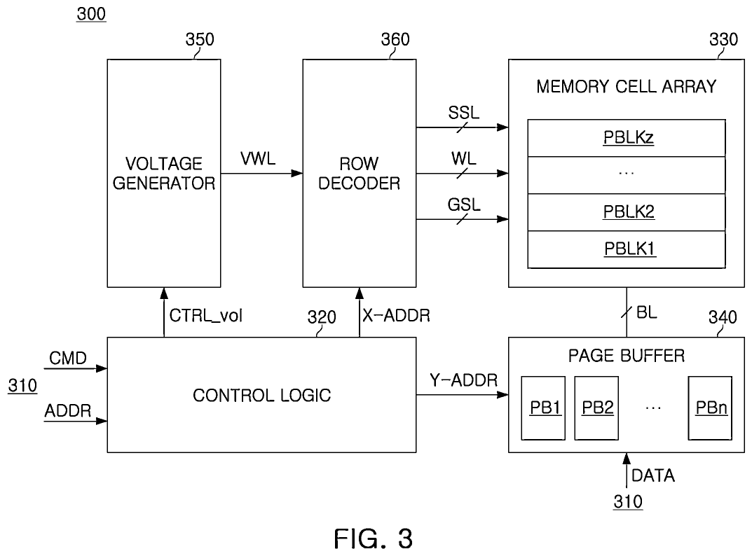

Hereinafter, before a storage device according to an exemplary embodiment of the present inventive concept is described in detail, a need for protection of metadata will be described in FIG. 2, and a structure of a memory block including a plurality of sub-blocks will be described in detail with reference to FIGS. 3 to 5.

FIG. 2 is a diagram schematically illustrating a storage space of a storage device according to an embodiment of the present inventive concept.

Referring to FIG. 2, in the storage device 100 as described with reference to FIG. 1, a non-volatile memory region provided by the non-volatile memory device 120 may include a meta region and a user region. The user region may store user data provided by the host, and the meta region may store metadata such as map data of the user region. In an embodiment, the non-volatile memory device 120 may include user blocks constituting the user region and meta blocks constituting the meta region.

In the non-volatile memory region, the meta region may have a size smaller relative to the user region, but an access frequency of the meta region may be greater than that of the user region.

For example, the storage controller 110 included in the storage device 100 may not include a separate memory device that stores metadata such as map data. When the storage controller 110 includes a separate memory device such as DRAM (dynamic random-access memory), map data representing address mapping between logical addresses and physical addresses may be stored in the memory device, and a logical address received from the host may be converted into a physical address with reference to the map data.

On the other hand, when the storage controller 110 does not include a separate memory device, in order to access the non-volatile memory device 120 using a logical address, map data may be obtained from the non-volatile memory device 120, and an address conversion may be performed by referring to the map data.

If the storage controller 110 performs random read operations that access the memory regions indicated by a plurality of non-consecutive logical addresses, the storage controller 110 may access the meta region each time it performs a read operation so as to find a physical address corresponding to the logical address and access the user region using the physical address. Even if the same number of accesses occurs in the meta region and the user region, since the meta region has a very small size compared to the user region, the meta block may be accessed at a very high frequency compared to the user block, for example, more than 100 times of the frequency of the user block.

Due to the physical characteristics of the memory block, when a read operation is performed on a memory cell of the memory block, a read disturbance phenomenon in which data in adjacent memory cells is damaged may occur. If a meta block is accessed more frequently than a user block, the meta block may be more vulnerable to read disturbance than the user block. If a UECC occurs in data stored in the meta block due to read disturbance of the meta block, not only may recovery of some data be impossible, but a malfunction may also occur in the storage device 100.

According to an embodiment of the present inventive concept, the storage device 100 may program original data into one or more first sub-blocks included in the meta block in a first level cell mode, and program mirrored data of the original data into one or more second blocks included in the meta block in a second mode having a bit density greater than that of the first level cell mode, thereby providing high reliability of the meta block and reducing a storage space occupied by the mirrored data.

Meanwhile, the present inventive concept is not limited to applications to meta blocks. For example, the storage device 100 may program original data of relatively high importance among user data into the first sub-block of the user block in an SLC mode, and program mirrored data of the original data into the second-block of the user block in a TLC mode, thereby providing higher reliability. In addition, the present inventive concept does not necessarily have to be applied to all meta blocks.

FIG. 3 is a view illustrating a nonvolatile memory device according to an exemplary embodiment of the present inventive concept.

A memory device 300 of FIG. 3 may correspond to the non-volatile memory device 120 in FIG. 1. Referring to FIG. 3, a non-volatile memory device 300 may include a control logic circuit 320, a memory cell array 330, a page buffer 340, a voltage generator 350, and a row decoder 360. Although not illustrated in FIG. 3, the non-volatile memory device 300 may further include a memory interface circuit 310, and may further include a column logic, a pre-decoder, a temperature sensor, a command decoder, an address decoder and the like.

The control logic circuit 320 may generally control various operations in the memory device 300. The control logic circuit 320 may output various control signals in response to a command CMD and/or an address ADDR from the memory interface circuit 310. For example, the control logic circuit 320 may output a voltage control signal CTRL_vol, a row address X-ADDR, and a column address Y-ADDR.

The memory cell array 330 may include a plurality of memory blocks BLK1 to BLKz (where z is a positive integer), and each of the memory blocks BLK1 to BLKz may include a plurality of memory cells. The memory cell array 330 may be connected to a page buffer unit 340 through bit lines BL, and may be connected to the row decoder 360 through word lines WL, string select lines SSL, and ground select lines GSL.

In an exemplary embodiment, the memory cell array 330 may include a three-dimensional memory cell array, and the three-dimensional memory cell array may include a plurality of NAND strings. Each NAND string may include memory cells each connected to the word lines vertically stacked on a substrate. U.S. Pat. Nos. 7,679,133, 8,553,466, 8,654,587, 8,559,235, and US Patent Application Publication No. 2011/0233648 are incorporated herein by reference in their entirety. In an exemplary embodiment, the memory cell array 330 may include a two-dimensional memory cell array, and the two-dimensional memory cell array may include a plurality of NAND strings arranged in row and column directions.

The page buffer 340 may include a plurality of page buffers PB1 to PBn (where n is an integer of 3 or more), and the plurality of page buffers PB1 to PBn may be respectively connected to memory cells through a plurality of bit lines BL. The page buffer 340 may select at least one bit line of the bit lines BL in response to a column address Y-ADDR. The page buffer 340 may operate as a write driver or a sense amplifier depending on an operation mode. For example, during a program operation, the page buffer 340 may apply bit line voltage corresponding to data to be programmed to the selected bit line. During a read operation, the page buffer 340 may sense data stored in a memory cell by sensing a current or voltage of the selected bit line.

The voltage generator 350 may generate various types of voltages to perform program, read, and erase operations based on a voltage control signal CTRL_vol. For example, the voltage generator 350 may generate a program voltage, a read voltage, a program verification voltage, an erase voltage and the like, as word line voltage VWL.

The row decoder 360 may select one of the plurality of word lines WL in response to the row address X-ADDR, and may select one of a plurality of string select lines SSL. For example, the row decoder 360 may apply the program voltage and the program verification voltage to the selected word line during the program operation, and may apply the read voltage to the selected word line during the read operation.

Each of the memory blocks BLK1 to BLKz may include a plurality of sub-blocks that can be erased independently from each other.

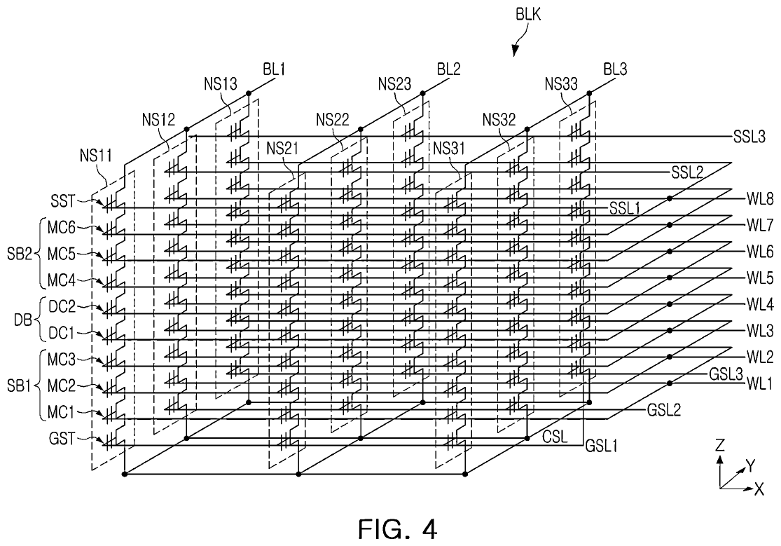

FIG. 4 is an equivalent circuit diagram of a memory block formed in a vertical structure.

When a non-volatile memory of a storage device is implemented as a 3D V-NAND type flash memory, a plurality of memory blocks included in the non-volatile memory may be respectively represented by an equivalent circuit as illustrated in FIG. 4.

A memory block BLK illustrated in FIG. 4 may represent a three-dimensional memory block formed on a substrate in a three-dimensional structure. For example, a plurality of cell strings included in the memory block BLK may be formed in a direction perpendicular to the substrate.

Referring to FIG. 4, the memory block BLK may include cell strings NS11 to NS33, word lines WL1 to WL8, bit lines BL1 to BL3, ground select lines GSL1 to GSL3, strings select lines SSL1 to SSL3 and a common source line CSL. Although it is illustrated in FIG. 4 that each of the cell strings NS11 to NS33 includes six memory cells MC1 to MC6 and two dummy cells DC1 and DC2 connected to eight word lines WL1 to WL8, aspects of the present inventive concept are not limited thereto.

For example, in each cell string, one or more dummy cells may be provided. In accordance with one embodiment, one or more dummy cells may be provided between a string select transistor SST and a sixth memory cell MC6. In accordance with another embodiment, in each cell string, one or more dummy cells may be provided between a ground select transistor GST and a first memory cell MC1.

The dummy cells DC1 and DC2 may have the same structure as the memory cells MC1 to MC6, and may be unprogrammed (for example, programming is prohibited) or programmed differently from the memory cells MC1 to MC6. For example, when the memory cells MC1 to MC6 are programmed to have two or more threshold voltage distributions, the dummy cells DC1 and DC2 may be programmed to have one threshold voltage distribution or a smaller number of threshold voltage distributions than that of the memory cells MC.

As illustrated in FIG. 4, each cell string (for example, NS11) may include a string select transistor SST, a plurality of memory cells MC1 to MC6, a plurality of dummy cells DC1 and DC2 and a ground select transistor GST, connected in series. The plurality of the memory cells MC1 to MC6 and the plurality of the dummy cells DC1 and DC2 may be respectively connected to the corresponding word lines WL1 to WL8. The ground select transistor GST may be connected to a corresponding ground select line (for example, GSL1). The string select transistor SST may be connected to a corresponding string select line (for example, SSL1), and may be connected to the corresponding bit lines BL1 to BL3. The ground select transistor GST may be connected to the common source line CSL.

The memory block BLK may include a plurality of sub-blocks SB1 and SB2 stacked vertically. The first sub-block SB1 may include the memory cells MC1 to MC3 connected to the first to third word lines WL1 to WL3, and the second sub-block SB2 may include the memory cells MC4 to MC6 connected to the sixth to eighth word lines WL6 to WL8. A dummy block DB including the dummy cells DC1 and DC2 connected to the fourth and fifth word lines WL4 and WL5 may be intervened between the first sub-block SB1 and the second sub-block SB2.

The sub-blocks SB1 and SB2 included in the memory block BLK may be individually erased. For example, in order to erase the second sub-block SB2, an erase body voltage may be applied to the common source line CSL, and an erase voltage may be applied to the sixth to eighth word lines WL6 to WL8 of the second sub-block SB2. The erase body voltage may have a voltage level relatively higher than the erase voltage, and the erase voltage may be a ground voltage. At this time, a voltage for preventing holes from being injected into the first sub-block may be applied to the fourth and fifth word lines WL4 and WL5 of the dummy block (DB in FIG. 4), and no voltage may be applied to the first to third word lines WL1 to WL3 of the first sub-block.

FIG. 4 illustrates a case in which one memory block BLK includes two sub-blocks SB1 and SB2, and the two sub-blocks SB1 and SB2 include the same number of memory cells. However, aspects of the present inventive concept are not limited thereto. For example, one memory block BLK may include three or more sub-blocks, and a number of memory cells included in each sub-block included in one memory block BLK may vary.

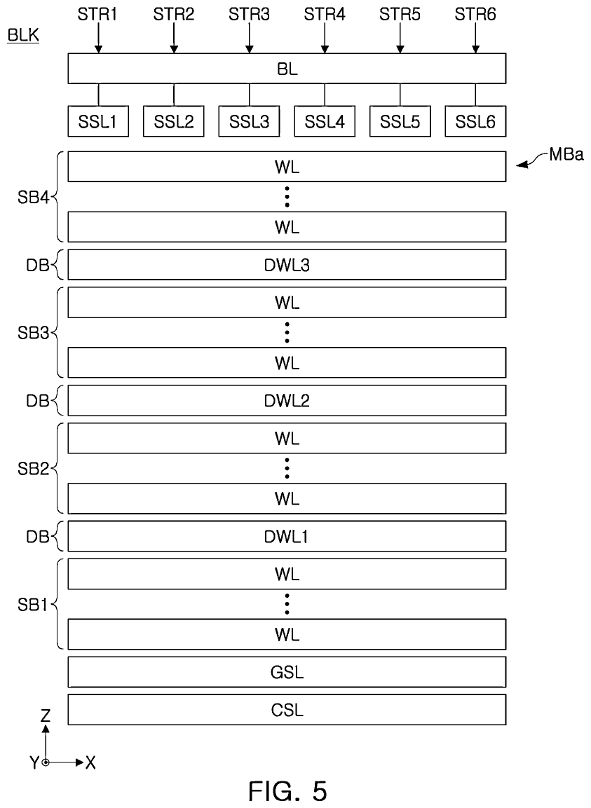

FIG. 5 is an exemplary block diagram illustrating a structure of a memory block.

FIG. 5 illustrates a memory block BLK divided into four sub-blocks SB1 to SB4. Similar to those described with reference to FIG. 4, the memory block BLK may include a plurality of cell strings, wherein in each cell string, string select transistors connected respectively to string select lines SSL1 to SSL6, a plurality of memory cells connected to word lines and a ground select transistor connected to a ground select line GSL are disposed in series in a vertical direction between a bit line BL and a common source line CSL. The plurality of memory cells may be connected to the word lines, respectively.

The word lines may include normal word lines WL connected to memory cells of the sub-blocks SB1 to SB4 and dummy word lines DWL1 to DWL3 connected to memory cells of dummy blocks DB. The sub-blocks SB1 to SB4 may be disposed in the vertical direction, and the dummy blocks DB may be interposed between the sub-blocks SB1 to SB4.

According to an embodiment of the present inventive concept, three of the four sub-blocks SB1 to SB4 are first sub-blocks and may store original data in an SLC mode, and the remaining sub-block is a second sub-block and may store mirrored data of the original data in a TLC mode.

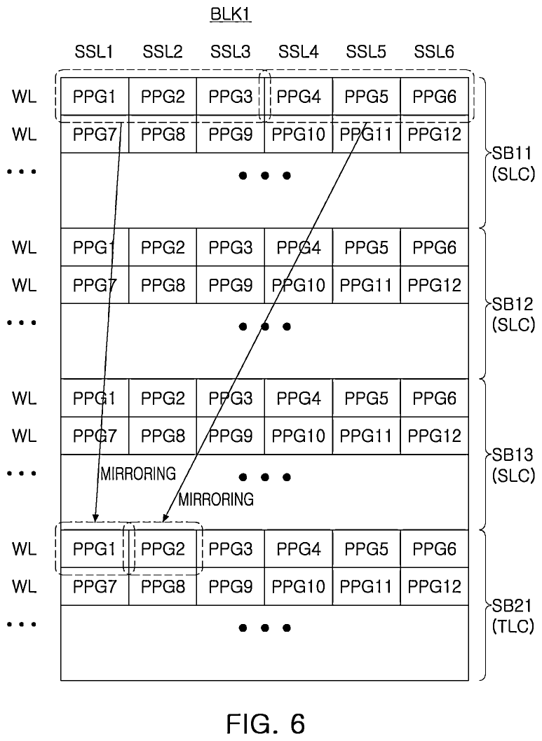

FIGS. 6 to 8 are diagrams illustrating operations of a storage device in detail according to an embodiment of the present inventive concept.

FIG. 6 illustrates a storage space of a first memory block BLK1 of a plurality of memory blocks included in the non-volatile memory device 120 as described with reference to FIGS. 1 to 5. The first memory block BLK1 may include a plurality of first sub-blocks SB11 to SB13 and one second sub-block SB21. Each of the sub-blocks SB11 to SB13 and SB21 may include a plurality of physical pages, including first to twelfth physical pages PPG1 to PPG12. A physical page may include memory cells specified by one of the word lines WL and one of the string select lines SSL1 to SS6.

In an embodiment, the plurality of first sub-blocks SB11 to SB 13 may be programmed in an SLC mode, and the second sub-block SB21 may be programmed in a TLC mode. More specifically, in the plurality of first sub-blocks SB11 to SB13, the memory cells may be programmed to have two threshold voltage distributions so that one memory cell may store one bit of data, while in the second sub-block SB21, the memory cells may be programmed to have eight threshold voltage distributions so that one memory cell may store three bits of data.

In the embodiment of FIG. 6, each of the sub-blocks SB11 to SB13 and SB21 may have the same size. The fact that the sub-blocks have the same size may mean that a number of memory cells and a number of word lines included in the sub-blocks are the same. When the sub-blocks SB11-SB13 and SB21 have the same size, a storage capacity of the second sub-block SB21 may be the same as a combined storage capacity of the three first sub-blocks SB11 to SB13. Mirrored data of original data stored in the remaining 75% of the storage space may be stored using only 25% of the storage space of the first memory block BLK1.

According to an embodiment of the present inventive concept, the storage device 100 as described with reference to FIG. 1 may use a plurality of sub-blocks included in one memory block to improve reliability while minimizing storage space loss of the memory block.

Specifically, the storage device 100 may increase reliability of original data itself by programming the original data in an SLC mode, and provide mirrored data when a UECC occurs in the original data, thereby supporting recovery of the original data. The storage device 100 may reduce a storage space occupied by the mirrored data by programming the mirrored data in a TLC mode.

According to an embodiment of the present inventive concept, since the original data and the mirrored data of the original data are included in the same memory block, it may be easier for the storage device to find the mirrored data.

Specifically, an operation of the storage controller 110 included in the storage device 100 to recover original data in which a UECC occurred may include finding a location where the mirrored data corresponding to the original data is stored in the non-volatile memory device 120, and obtaining the mirrored data from the location where the mirrored data is stored. If the first sub-block in which the original data is stored and the second sub-block in which the mirrored data is stored are included in the same memory block BLK1, the block addresses of the original data and the mirrored data are the same, while only the page addresses are different, so that an address of the location where the mirrored data is stored may be found by performing a simple operation.

For example, physical pages included in the first sub-blocks SB11, SB12 and SB13 may have page addresses that are consecutive to each other, and physical pages included in the second sub-block SB21 may also have page addresses that are consecutive to each other. The physical pages in the first sub-blocks SB11, SB12 and SB13 may be programmed in an order of the page addresses, and the physical pages in the second sub-block SB21 may also be programmed in an order of the page addresses.

The storage controller 110 may determine a first relative address indicating a sequence of a first physical page storing original data where a UECC occurs in the physical pages of the first sub-blocks SB11, SB12 and SB13. In addition, the storage controller 110 may determine a ratio of a storage space occupied by the original data to a storage space occupied by the mirrored data. The storage controller 110 may calculate a second relative address indicating a sequence of a second physical page storing mirrored data in the second sub-block SB21 based on the first relative address and the ratio of the storage spaces. The storage controller 110 may find an address of a location where the mirrored data is stored based on the second relative address.

In the example of FIG. 6, the original data may occupy three times the storage space compared to the mirrored data. In other words, a ratio of the storage spaces may be ‘three (3).’ If a UECC occurs in the original data stored in the fifth physical page PPG5 of the first sub-block SB11, the first relative address of the storage controller 110 may be ‘5.’ The second relative address may be calculated as ‘2’ by dividing the first relative address ‘5’ by the ratio of the storage spaces ‘3’ and rounding up the result thereof. In addition, the storage controller 110 may determine that the mirrored data of the original data is stored in the second physical page PPG2 of the second sub-block SB21.

According to an embodiment of the present inventive concept, the storage controller 110 may not store separate data representing a mapping between original data and mirrored data, but perform a simple operation based on the address of a location where the original data is stored, thereby finding an address of a location where the mirrored data is stored.

In an embodiment, when an amount of unit data that can be programmed into one physical page of the second sub-block is programmed into the first sub-block, the non-volatile memory device may be controlled to perform a mirroring operation for programming mirrored data of the unit data into the second sub-block.

For example, when the original data is programmed into the first to third physical pages PPG1 to PPG3 of the first sub-block SB11, the mirrored data copying the original data may be programmed into the first page PPG1 of the second sub-block SB2. In addition, when the original data is programmed into the fourth to sixth physical pages PPG4 to PPG6 of the first sub-block SB11, the mirrored data copying the original data may be programmed into the second page PPG2 of the second sub-block SB2.

According to an embodiment of the present inventive concept, the original data programmed into the first sub-block may be immediately mirrored into the second sub-block when it reaches a predetermined amount, thereby enhancing reliability of the recently programmed original data.

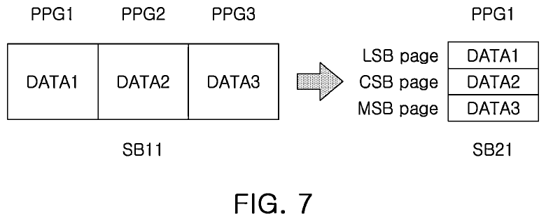

FIG. 7 briefly illustrates the first to third physical pages PPG1 to PPG3 of the first sub-block SB11 and the first physical page PPG1 of the second sub-block SB21. As described above, the first sub-block SB11 may store one bit of data in one memory cell in an SLC mode, while the second sub-block SB21 may store three bits of data in one memory cell in a TLC mode.

The storage space of the physical pages of the second sub-block SB21 may be managed as three logical pages. For example, the first physical page PPG1 may include an LSB page, a CSB page and an MSB page. The LSB page may consist of least significant bits (LSBs) of the memory cells each storing three bits, the CBS page may consist of central significant bits (CSBs) of the memory cells, and the MSB may consist of most significant bits (MSBs) of the memory cells.

A mirroring operation may be performed as follows: first to third original data DATA1, DATA2 and DATA3 programmed into the first to third physical pages PPG1 to PPG3 of the first sub-block SB11 are organized in a manner that the first original data DATA1 is stored in the LSB page, the second original data DATA2 is stored in the CSB page and the third original data DATA3 is stored in in the MSB page, and then are programmed into the first physical page PPG1 in the second sub-block SB21.

The mirroring operation may include reading data from the first to third physical pages PPG1 to PPG3 of the first sub-block SB11, and programming the read data into the second sub-block SB21. In an embodiment, the non-volatile memory device 120 may perform a copy-back program operation in response to a mirroring operation request from the storage controller 110.

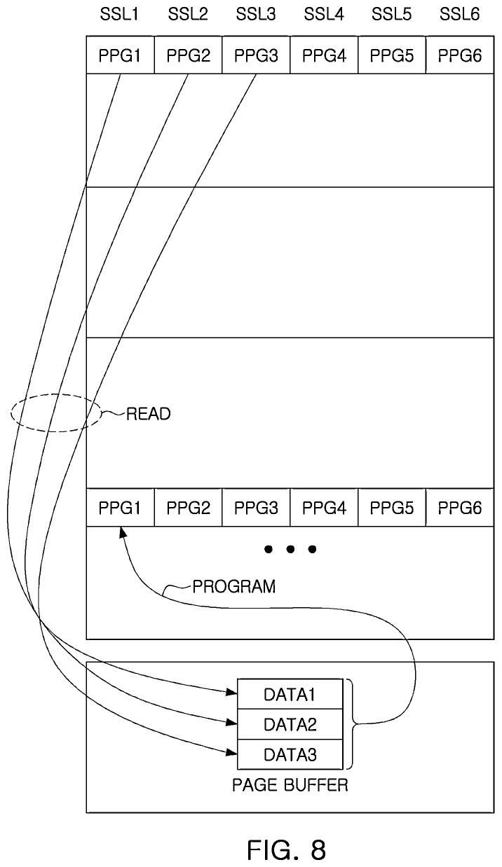

FIG. 8 is shown to schematically illustrate a copy-back program operation of a non-volatile memory device.

A copy-back program operation may refer to an operation of reading data programmed in a certain memory block, buffering the read data into a page buffer, and programming the buffered data into the memory block or another memory block included in the same plane. Here, a plane may refer to a unit that has one page buffer, and can be controlled independently from other planes using the page buffer.

According to an embodiment of the present inventive concept, the non-volatile memory device 120 sequentially may read the first to third data DATA1 to DATA3 programmed in the physical pages PPG1 to PPG3 of the first sub-block, and buffer the first to third data DATA1 to DATA3 into the page buffer. In addition, the non-volatile memory device 120 may program the buffered first to third data DATA1 to DATA3 into the physical page PPG1 of the second sub-block. Since the first to third data DATA1 to DATA3 are not output to the storage controller 110 and can be processed within the plane, a data path for the mirroring operation may be shortened and a speed of the mirroring operation may be improved.

In the examples of FIGS. 6 to 8, it has been described that the data is programmed into the first sub-blocks SB11 to SB13 in an SLC mode, while the data is programmed in into the second sub-block SB21 an TLC mode. However, aspects of the present inventive concept are not limited thereto.

Original data may be programmed into a plurality of first sub-blocks in a first level cell mode, and mirrored data of the original data may be programmed in a second level cell mode having a bit density greater than that of the first level cell mode.

Specifically, a ratio of the bit density of the second level cell mode to the bit density of the first level cell mode may be inversely proportional to a ratio of a number of the second sub-block to a number of the first sub-blocks

As a first example, when one memory block includes three sub-blocks of the same size, the original data may be programmed into two first sub-blocks in the SLC mode, and the mirrored data may be programmed into one second sub-block in a multi-level cell (MLC) mode, in which two bits of data is stored in one memory cell.

As a second example, when one memory block includes five sub-blocks of the same size, the original data may be programmed into four first sub-blocks in the SLC mode, and the mirrored data may be programmed into one second sub-block in a quadruple level cell (QLC) mode, in which four bits of data is stored in one memory cell.

As a third example, the original data may be programmed into three first sub-blocks in the MLC mode, and the mirrored data may be programmed into two second sub-blocks in a TLC mode.

The present inventive concept is not limited to the embodiments described above, and the storage device 100 may perform a mirroring operation according to various embodiments.

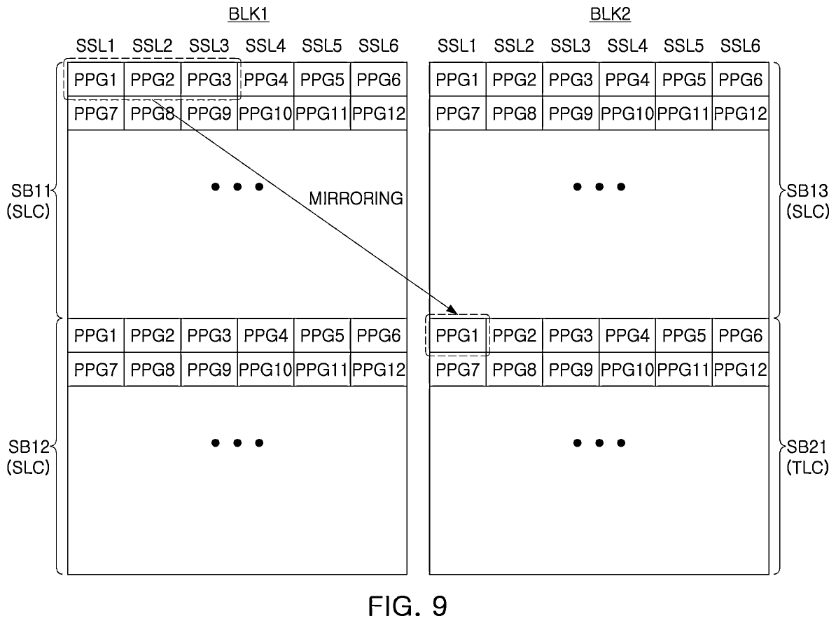

FIGS. 9 to 11 are diagrams illustrating operations of a storage device according to various embodiments of the present inventive concept.

Referring to FIG. 9, a mirroring operation according to an embodiment of the present inventive concept may be performed on a group of memory blocks. In FIG. 9, a group including two memory blocks BLK1 and BLK2 each including two sub-blocks is illustrated.

According to an embodiment of the present inventive concept, the first memory block BLK1 may include first sub-blocks SB11 and SB12 programmed in an SLC mode, and the second memory block BLK2 may include a first sub-block SB13 programmed in the SLC mode and a second sub-block SB21 programmed in a TLC mode.

The storage controller 110 may control the non-volatile memory device 120 to program original data into the first sub-blocks SB11 to SB13. In addition, the storage controller 110 may control the non-volatile memory device 120 to program mirrored data of the original data into the second sub-block SB21. FIG. 9 illustrates a case in which data programmed into the first to third physical pages PPG1 to PPG3 of the first sub-block SB11 are mirrored to a first physical page PPG1 of the second sub-block SB21.

A number of the sub-blocks included in one memory block in the non-volatile memory device 120 may be fixed when manufacturing the non-volatile memory device 120. According to an embodiment of the present inventive concept, two or more memory blocks may be grouped into one group, and a mirroring operation may be performed on the group basis, whereby various program modes may be applied to the first sub-block and the second sub-block without being limited by a number of the sub-blocks included in one memory block.

For example, when one memory block includes two sub-blocks as in the example of FIG. 9, it is possible to configure three first sub-blocks SB11, SB12 and SB13 to be programmed in the SLC mode and one second sub blocks SB21 to be programmed in the TLC mode, by grouping two memory blocks,

In an embodiment, one group of memory blocks may be included in one plane. When one group of memory blocks are included in one plane, the non-volatile memory device 120 may perform a copy-back program operation to perform a mirroring operation on the memory blocks in response to a control of the storage controller 110.

In an embodiment, a group of memory blocks may be memory blocks with consecutive addresses. For example, when the addresses of the first and second memory blocks BLK1 and BLK2 are consecutive, an address calculation may be easier for referring to the second sub-block SB21 in order to recover the original data stored in the first sub-blocks SB11, SB12 and SB13.

Specifically, when addresses of the first and second memory blocks BLK1 and BLK2 are consecutive, addresses of the physical pages of the first sub-blocks SB11, SB12, and SB13 may also be consecutive. Similar to those described with reference to FIG. 6, the storage controller 110 may find a second relative address of a second physical page where mirrored data are stored, based on a first relative address of the first physical page where original data with a UECC occurring is stored and a ratio of storage spaces of the original data and the mirrored data.

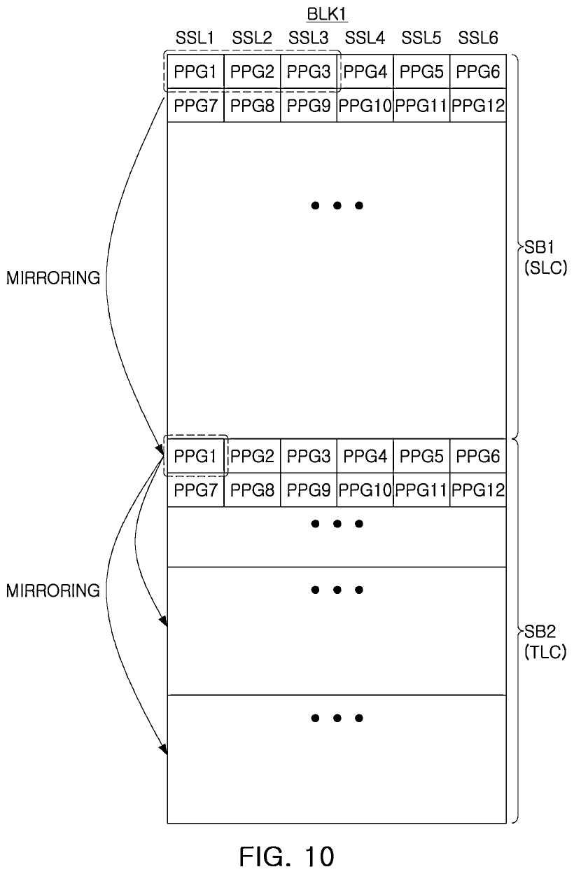

Referring to FIG. 10, the storage controller 110 may also control the non-volatile memory device 120 to program two or more sets of mirrored data copying certain original data into one memory block. FIG. 10 illustrates a first memory block BLK1 including one first sub-block SB1 and one second sub-block SB2. In an embodiment, the first sub-block SB1 and the second sub-block SB2 may have the same size.

According to an embodiment of the present inventive concept, original data may be programmed into the first sub-block SB1 in a SLC mode, and three sets of mirrored data identical to the original data may be programmed into the second sub-block SB2 in a TLC mode.

For example, when an amount of unit data that can be programmed into the physical page of the second sub-block SB2 is programmed into the first sub-block SB1, mirrored data of the unit data may be is programmed into the second sub-block SB2.

When programming of the original data into the entire storage space of the first sub-block SB1 is completed, one set of the mirrored data can be programmed in 33% of a storage space of the second sub-block SB2. Another two sets of the mirrored data may be programmed into the remaining storage space of the second sub-block SB2.

Aspects of the present inventive concept are not limited to programming three sets of the mirrored data into the second sub-block SB2 in the TLC mode. Specifically, the number of the sets of the mirrored data programmed into the second sub-block SB2 may be determined based on a ratio of a bit density of the second level cell mode to a bit density of the first level cell mode.

For example, two sets of the mirrored data may be programmed into the second sub-block SB2 in an MLC mode, and four sets of the mirrored data may be programmed into the second sub-block SB2 in a QLC mode. In addition, the original data may be programmed into the first sub-block SB1 in the MLC mode, and two sets of the mirrored data may be programmed into the second sub-block SB2 in the QLC mode.

According to an embodiment of the present inventive concept, the storage device 100 may further improve reliability by recovering the original data using the remaining set of the mirrored data, even if a UECC occurs not only in the original data but also in one set of the mirrored data.

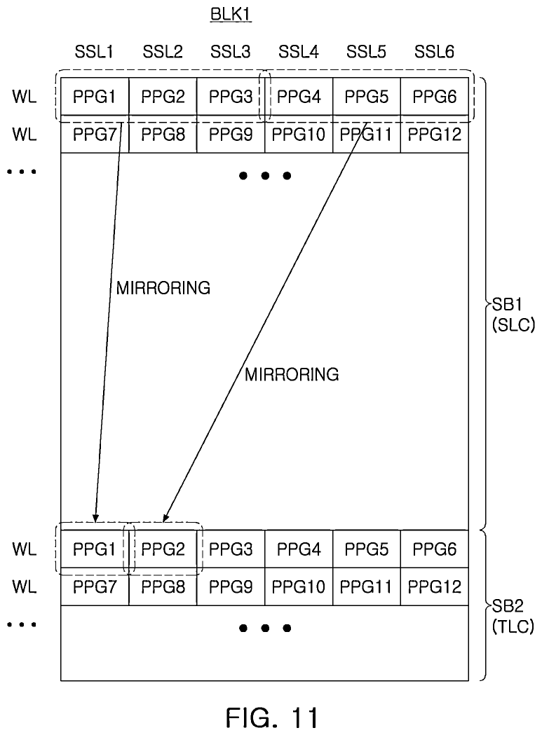

Referring to FIG. 11, one memory block may include a plurality of sub-blocks of different sizes, and according to an embodiment of the present inventive concept, a mirroring operation may be performed by applying different program modes to the sub-blocks of different sizes.

In the example of FIG. 11, a first memory block BLK1 may include a first sub-block SB1 and a second sub-block SB2 having a size smaller than that of the first sub-block SB1. The fact that the second sub-block SB2 has a size smaller than that of the first sub-block SB1 may mean that a number of memory cells and a number of word lines included in the second sub-block SB2 are less than those in the first sub-block SB1.

If original data and mirrored data are to be stored in program modes with the same bit density into the first sub-block SB1 and second sub-block SB2 of different sizes, a portion of the original data may not be mirrored or a storage space of the sub-block of a larger size may be wasted.

According to an embodiment of the present inventive concept, the storage controller 110 may control the non-volatile memory device 120 to program the original data into the first sub-block SB1 in a first level cell mode, and program the mirrored data into the second sub-block SB1 having a size smaller than that of the first sub-block SB1 in a second level cell mode having a bit density greater than that of the first level cell mode. The first level cell mode and the second level cell mode may be determined according to a ratio of sizes of the first sub block SB1 and the second sub block SB2.

In the example of FIG. 11, the size of the first sub-block SB1 may be implemented to be three times larger than the size of the second sub-block SB2. The storage controller 110 may control the non-volatile memory device 120 to program the original data into the first sub-block SB1 in the SLC mode and program the mirrored data copying the original data into the second sub-block SB2 in the TLC mode. Accordingly, the storage device 100 may store the original data and the mirrored data in the first memory block BLK1 without wasting a storage space of the first memory block BLK1.

However, aspects of the present inventive concept are not limited to the example of FIG. 11, relative sizes of the first sub-block SB1 and the second sub-block SB2, and the program modes of the first sub-block SB1 and the second sub-block SB2 determined according to the relative sizes may vary. For example, a ratio of the bit density of the second level cell mode to a bit density of the first level cell mode may be inversely proportional to a ratio of a size of the second sub-block to a size of the first sub-block.

With reference to FIGS. 6 to 11, various embodiments have been described in which the storage device 100 improves data reliability by programming the mirrored data of the original data programmed in the first sub-block into the second sub-block. However, aspects of the present inventive concept are not limited to the cases of mirroring data to improve data reliability. For example, the present inventive concept may also be applied to a case of programming parity data generated based on original data to improve data reliability.

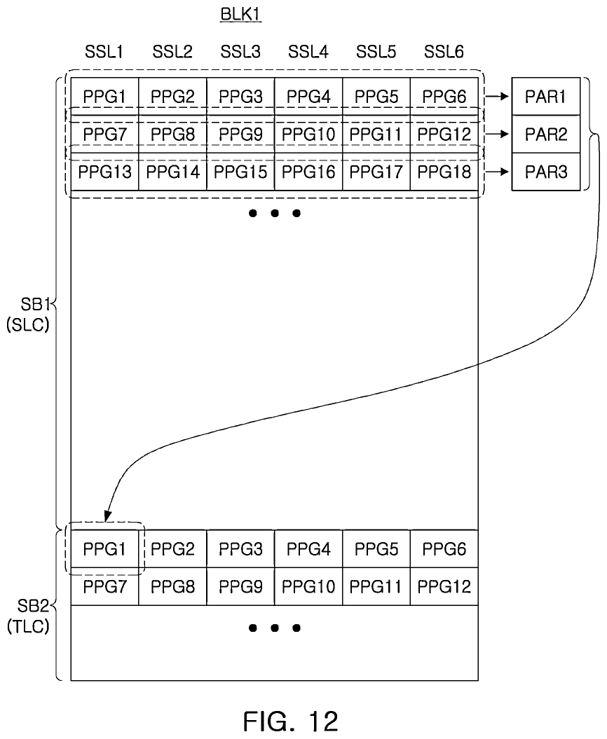

FIG. 12 is a diagram illustrating an operation of a storage device according to an embodiment of the present inventive concept.

Referring to FIG. 12, a first memory block BLK1 may include a first sub-block SB1 and a second sub-block SB2. According to an embodiment of the present inventive concept, the storage controller 110 may control the non-volatile device 120 to program original data into the first sub-block SB1 in a first level cell mode, and program parity data generated by a parity operation on the original data into the second sub-block SB2 in a second level cell mode having a bit density greater than that of the first level cell mode. For example, the first level cell mode may be an SLC mode, and the second level cell mode may be a TLC mode.

In an embodiment, the parity data may be generated by performing a parity operation on a plurality of original data chunks including the original data. For example, a data chunk may refer to an amount of data that can be programmed into one physical page of the first sub-block. The parity operation may include an operation of generating a parity data chunk of the same size as each original data chunk by performing an XOR operation on the same digits of bits in each of a plurality of original data chunks.

In the example of FIG. 12, a parity operation may be performed on six original data chunks included in first to sixth physical pages PPG1 to PPG6 of the first sub-block SB1, thereby generating a first parity data chunk PAR1. In an embodiment, the non-volatile memory device 120 may support an XOR operation on each data bit of the data chunks using a page buffer connected to the first memory block BLK1. For example, when the non-volatile memory device 120 sequentially reads the original data chunks stored in the first to sixth physical pages PPG1 to PPG6 into the page buffer, an XOR operation may be performed on each data bit of the previously buffered data chunks and the data chunks read into the current page buffer.

Similarly, a parity operation may be performed on six original data chunks included in seventh to twelfth physical pages PPG7 to PPG12 of the first sub-block SB1, thereby generating a second parity data chunk PAR2. In addition, a parity operation may be performed on six original data chunks included in thirteenth to eighteenth physical pages PPG13 to PPG18 of the first sub-block SB1, thereby generating a third parity data chunk PAR3.

An amount of data of the first to third parity data chunks PAR1 to PAR3 may be equal to an amount of data that can be programmed into one physical page of the second sub-block SB2 in the second level cell mode. The first to third parity data chunks PAR1 to PAR3 may be programmed into the first physical page PPG1 of the second sub-block SB2 in the second level cell mode.

If a UECC occurs in any one of the original data chunks programmed into the first to eighteenth physical pages PPG1 to PPG18 of the first sub-block (SB1), the storage controller 110 may recover the data chunk using any one of the parity data chunks PAR1 to PAR3 programmed into the first physical page. For example, when a UECC occurs in a data chunk programmed into the first physical page PPG1 of the first sub-block SB1, the storage controller 110 may obtain the data chunks from the physical pages PPG2 to PPG6, perform a read operation on the first physical phage PPG1 of the second sub-block SB2 to obtain a first parity data chunk PAR1, and perform a parity operation on the data chunks and the first parity data chunk PAR1 to recover the data chunk stored in the first physical page PPG1.

The storage controller 110 may find an address of a physical page in which a parity data associated with the original data is stored by a method similar to that described with reference to FIG. 6. The storage controller 110 may determine a first relative address of the first physical page in which the original data with the UECC occurred in the first sub-block SB1 is stored. Furthermore, the storage controller 110 may calculate a second relative address of the second physical page, in which the parity data is stored, in the second sub-block SB2, based on the first relative address and a ratio of a storage space occupied by the original data to a storage space occupied by the parity data.

In the example of FIG. 12, the original data may occupy 6×3=18 times as much storage space as the parity data. That is, the ratio of the storage spaces may be ‘eighteen (18).’ The storage controller 110 may calculate the second relative address by dividing the first relative address by the ratio of the storage spaces and rounding up the result thereof.

In FIG. 12, the sizes of the first sub-block SB1 and the second sub-block SB2 are shown to be different from each other. However, aspects of the present inventive concept are not limited thereto, and the sizes of the sub-blocks may be the same. In addition, numbers of the first sub-blocks SB1 and the second sub-blocks SB2 may not be limited.

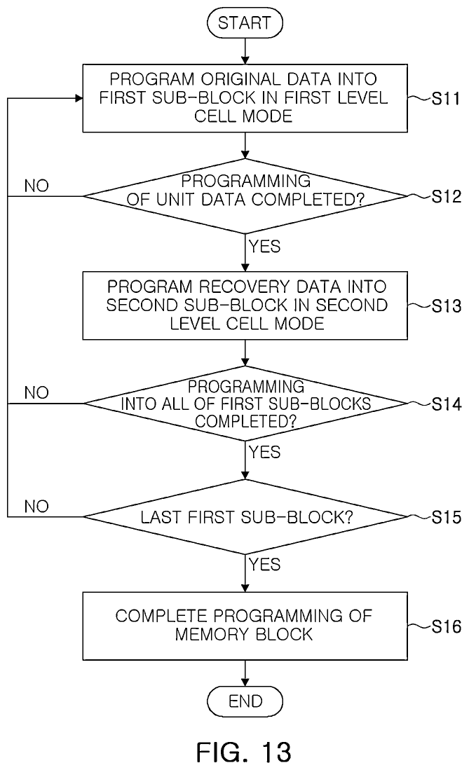

Hereinafter, a program operation and a read operation of the storage device 100 according to an embodiment of the present inventive concept will be described with reference to FIGS. 13 to 15.

FIG. 13 is a flowchart illustrating a program operation of a storage device according to an embodiment of the present inventive concept.

In step S11, a storage controller 110 may control a non-volatile memory device 120 to program original data into a first sub-block included in a first memory block in a first level cell mode. The original data may be programmed into physical pages included in the first sub-block in a predetermined order determined according to addresses of the physical pages.

In step S12, the storage controller 110 may determine whether programming of unit data in the first sub-block has been completed. For example, the unit data may be determined based on an amount of recovery data to be programmed into one physical page of a second sub-block.

As a first example, when the recovery data is mirrored data, the unit data may be an amount of data that can be programmed into one physical page of the second sub-block in a second level cell mode. When the first level cell mode is an SLC mode and the second level cell mode is a TLC mode, the unit data may be an amount of data that can be programmed into three physical pages of the first sub-block.

As a second example, when the recovery data is parity data, the unit data may be data corresponding to an amount of parity data that can be programmed into one physical page of the second sub-block in a second level cell mode. When the first level cell mode is an SLC mode and the second level cell mode is a TLC mode, and a parity operation is performed on six data chunks to generate one parity data chunk, the data may be an amount of data that can be programmed in eighteen (18) physical pages of the first sub-block.

If the programming of the unit data is not completed (“NO” in step S12), the storage controller 110 may control the non-volatile memory device 120 to consecutively program the original data into the first sub-block in step S11.

If the programming of the unit data is completed (“YES” in step S12), in step S13, the storage controller 110 may control the non-volatile memory device 120 to program the recovery data of the unit data into the second sub-block in the second level cell mode.

As a first example, when the recovery data is mirrored data, the storage controller 110 may control the non-volatile memory device 120 to store the mirrored data copying the unit data into the second sub-block. In an embodiment, the storage controller 110 may control a copy-back program operation in order for the non-volatile memory device 120 to program the mirrored data.

As a second example, when the recovery data is parity data, the storage controller 110 may control the non-volatile memory device 120 to store the parity data for the unit data into the second sub-block. In an embodiment, the storage controller 110 may control the non-volatile memory device 120 to generate the parity data by performing an XOR operation on a page buffer and program the generated parity data.

The second sub-block may be included in the same memory block as the first sub-block. Furthermore, the second sub-block may be included in the same group of memory blocks as the first sub-block.

In step S14, the storage controller 110 may determine whether the programming into the first sub-block has been completed. For example, the physical pages included in the first sub-block may be programmed in an order determined according to the page addresses, and it may be determined whether the last physical page has been programmed.

If programming into the first sub-block has not been completed (“NO” in step S14), the storage controller 110 may return to step S11 and control the non-volatile memory device 120 to continue programming the original data into the next page of the first sub-block.

If programming into the first sub-block has not been completed (“YES” in step S14), the storage controller 110 may determine whether the first sub-block is the last first sub-block included in the memory block in step S15.

If the first sub-block is not the last first sub-block (“NO” in step S15), the storage controller 110 may repeatedly perform steps S11 to S14 for the first sub-block in the next order.

If the first sub-block is the last first sub-block (“YES” in step S15), the storage controller 110 may complete the program operation for the memory block including the first sub-block in step S16.

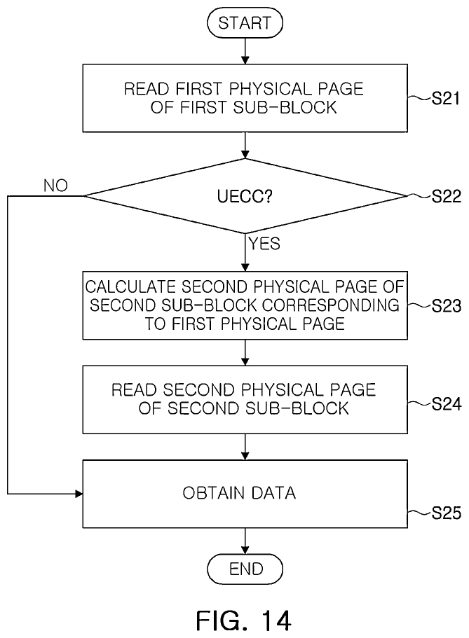

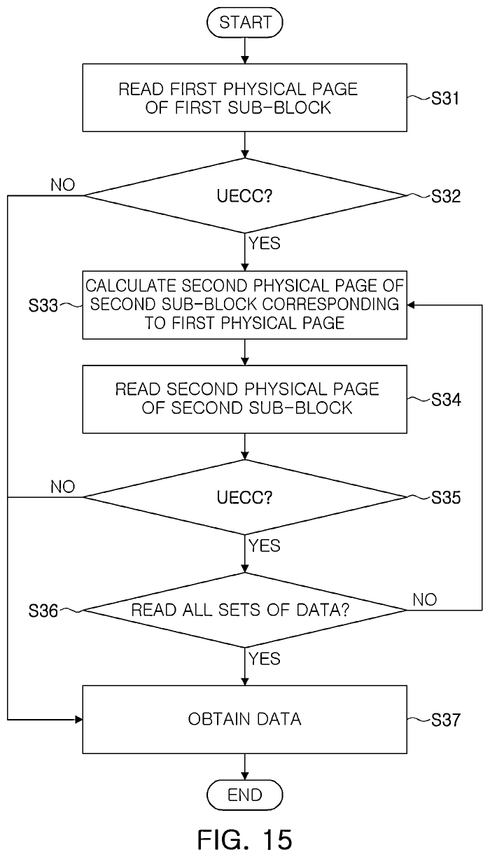

FIGS. 14 and 15 are flowcharts illustrating a read operation of a storage device according to an embodiment of the present inventive concept.

FIG. 14 illustrates a read operation when the storage device 100 includes a set of recovery data for original data.

In step S21, a storage controller 110 may control a non-volatile memory device 120 to read a first physical page of a first sub-block. As described above, the first sub-block may include original data. In an embodiment, the original data may be metadata, and the storage controller 110 may request the metadata to the first physical page of the non-volatile memory device 120 in order to control an operation of the storage device 100 with reference to the metadata. However, the present inventive concept is not limited thereto, and the original data may be user data.

In step S22, the storage controller 110 may determine whether a UECC has occurred in the obtained original data. For example, the storage controller 110 may detect and correct errors in the original data output from the non-volatile memory device 120 using an ECC engine 114 as described with reference to FIG. 1. If a number of error bits in the original data exceeds an error correction limit of the ECC engine 114, the storage controller 110 may determine that a UECC has occurred in the original data.

If a UECC has not occurred in the original data (“NO” in step S22), the storage controller 110 may obtain the original data with the error corrected in step S25. For example, if the original data is metadata, the storage controller 110 may obtain the original data and control an operation of the storage device 100 using the original data.

If a UECC has occurred in the original data (“YES” in step S22), the storage controller 110 may calculate an address of a second physical page corresponding to the first physical page in a second sub-block associated with the first sub-block in step S23.

As described with reference to FIGS. 6, 9, and 12, the storage controller 110 may calculate a second relative address of the second page based on a first relative address of the first physical page and a ratio of storage spaces of the original data and the recovery data. Furthermore, the storage controller 110 may calculate the address of the second physical page based on the second relative address.

In step S24, the storage controller 110 may control the non-volatile memory device 120 to read the second physical page of the second sub-block.

In step S25, the storage controller 110 may recover the original data using data read from the second physical page of the second sub-block. As a first example, the storage controller may use mirrored data read from the second physical page of the second sub-block as the original data. As a second example, the storage controller 110 may further obtain a plurality of original data chunks associated with the original data from the non-volatile memory device 120, and perform a parity operation on the original data chunks and parity data to recover the original data.

FIG. 15 illustrates a read operation when a storage device has two or more sets of recovery data for original data.

Steps S31 to S34 may be substantially the same as steps S21 to S24 described with reference to FIG. 14, respectively. Meanwhile, there may be a possibility that a UECC may also occur in the recovery data read in step S34.

In step S35, a storage controller 110 may determine whether a UECC has occurred in the recovery data read from the second physical page.

If a UECC has not occurred in the recovery data (“NO” in step S35), the storage controller 110 may obtain the original data using the recovery data in step S37.

If a UECC has occurred in the recovery data (“YES” in step S35), the storage controller 110 may determine whether all sets of the recovery data have been read in step S36.

If all sets of recovery data have not yet been read (“NO” in step S36), the storage controller 110 may return to step S33, calculate the second physical page in which the next set of the recovery data is stored, and perform steps S34 and S35.

If all sets of recovery data have been read (“YES” in step S36), the storage controller 110 may stop searching for the next set of the recovery data, and obtain unrecovered data in step S37.

According to the embodiments of the present inventive concept described with reference to FIGS. 1 to 15, the storage device 100 may program original data into one or more first sub-blocks of a plurality of sub-blocks included in one memory block or a group of memory blocks in a first level cell mode, and program recovery data of the original data into one or more second sub-blocks of the plurality of sub-blocks in a second level cell mode having a bit density greater than that of the first level cell mode.

According to an embodiment of the present inventive concept, the storage device 100 may improve data reliability while reducing a size of a storage space occupied by recovery data in a meta block or a user block that stores important user data.

The storage device 100 may store original data or recovery data for each sub-block included in a memory block, and therefore, when a UECC occurs in a portion of data, since only the sub-block containing the portion of data can be processed as a bad block and the use thereof can be prohibited, a loss of a storage space of memory blocks may be alleviated.

In addition, the storage device 100 may store original data and recovery data in sub-blocks included in one memory block or a group of memory blocks with addresses adjacent to each other, and therefore, the recovery data corresponding to the original data in which a UECC has occurred may be found with a simple address calculation. Accordingly, recovery performance of the storage device 100 may be improved.

Hereinafter, examples of a structure of a non-volatile memory device that can be applied to the storage device according to the embodiments of the present inventive concept described with reference to FIGS. 1 to 15 will be described in detail.

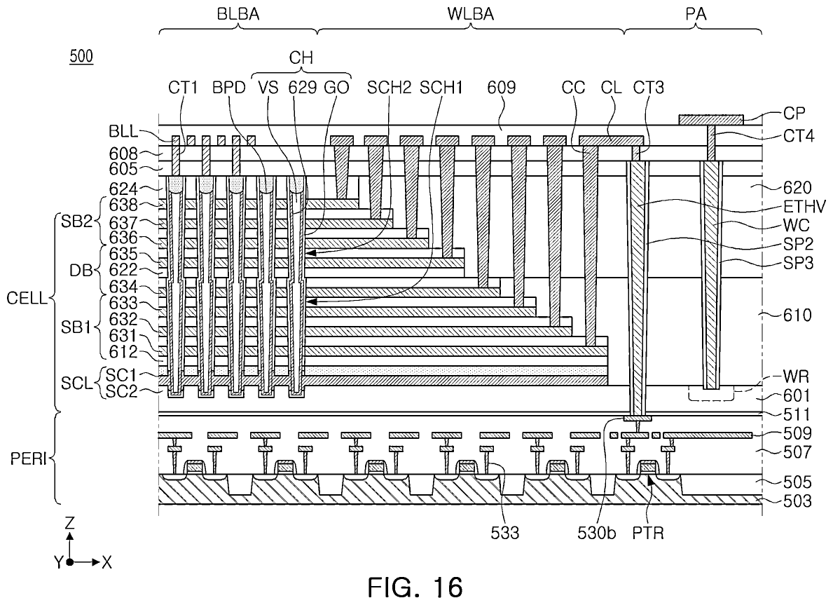

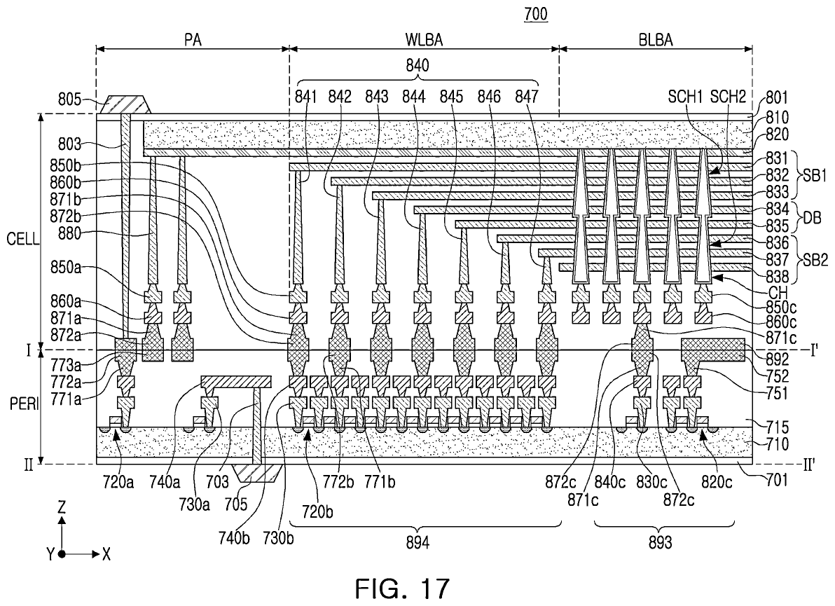

FIGS. 16 and 17 are cross-sectional views illustrating a non-volatile memory device including sub-blocks.

Referring to FIG. 16, a non-volatile memory device 500 may have a COP (Cell on Peri) structure. The COP structure may refer to a structure in which an upper chip including a cell region CELL is disposed on a lower chip including a peripheral circuit region PERI. The cell region CELL may include memory blocks BLK arranged side by side in a second direction Y. Most of the memory blocks BLK may be memory blocks in which program/read/erase operations of data are performed. In addition, some of the memory blocks may be dummy blocks in which program/read/erase operations of data are not performed. The memory blocks may be separated from each other by first separation insulating lines SL1. In FIG. 16, one of the memory blocks is illustrated. The memory blocks may each include a bit line bonding area BLBA, a word line bonding area WLBA and an external pad bonding area PA.

The peripheral circuit region PERI may include a first substrate 503. The first substrate 503 may be a silicon single crystal substrate or a silicon on insulator (SOI) substrate. A device isolation film 505 may be disposed on the first substrate 503 to define active regions. Peripheral transistors PTR may be disposed on the active regions. The peripheral transistors PTR may each include a peripheral gate electrode, a peripheral gate insulating film and peripheral source/drain regions disposed in the first substrate 503 adjacent to both sides thereof. The peripheral transistors PTR may be covered with a peripheral interlayer insulating film 507. The peripheral interlayer insulating film 507 may have a single-film or multi-film structure of at least one of a silicon oxide film, a silicon nitride film, a silicon oxynitride film and a porous insulating film. Peripheral interconnections 509 and peripheral contacts 533 may be disposed within the peripheral interlayer insulating film 507. The peripheral interconnections 509 and the peripheral contacts 533 may include a conductive film.

Some of the peripheral interconnections 509 and the peripheral contacts 533 may be electrically connected to the peripheral transistors PTR. The peripheral interconnections 509 and the peripheral transistors PTR may form the page buffer 340 and the row decoder 360 described with reference to FIG. 3. The peripheral circuit region PERI may include peripheral conductive pads 530b disposed at an upper end thereof.

An etch stop film 511 may be disposed on the peripheral circuit region PERI. The etch stop film 511 may include a material having etch selectivity with respect to a second substrate 601 and the peripheral interlayer insulating film 507. For example, the etch stop film 511 may include silicon nitride or silicon oxide. The etch stop film 511 may also be called an ‘adhesive film.’

The memory block included in the cell region CELL may include the second substrate 601, a source structure SCL, word lines 631 to 638 alternately stacked with interlayer insulating films 612, 622 and 624, and first to third upper insulating films 605, 608 and 609, that are sequentially stacked. The second substrate 601 may be, for example, a silicon single crystal layer, a silicon epitaxial layer or an SOI substrate. For example, the second substrate 601 may be doped with impurities of a first conductivity type. The impurities of the first conductivity type may be, for example, P-type boron. Alternatively, the impurities of the first conductivity type may be N-type arsenic or phosphorus.

The word lines 631 to 638 may include, for example, at least one selected from a doped semiconductor (doped silicon or the like), a metal (tungsten, copper, aluminum or the like), a conductive metal nitride (titanium nitride, tantalum nitride or the like), a transition metal (titanium, tantalum or the like) or the like. The electrode interlayer insulating films 612, 622, and 624 may include a single-film or multi-film of at least one selected from a silicon oxide film, a silicon nitride film, a silicon oxynitride film and a porous insulating film.

The source structure SCL may include a first source pattern SC1 interposed between the electrode interlayer insulating film 612 located in a lowest layer and the second substrate 601 and a second source pattern SC2 interposed between the first source pattern SC1 and the second substrate 601. The first source pattern SC1 may include a semiconductor pattern doped with impurities, for example, polysilicon doped with impurities of a first conductivity type.

The second source pattern SC2 may include a semiconductor pattern doped with impurities, for example, polysilicon doped with impurities. The second source pattern SC2 may further include a semiconductor material different from that of the first source pattern SC1. The conductivity type of the impurities doped into the second source pattern SC2 may be the same as the conductivity type of the impurities doped into the first source pattern SC1. A concentration of the impurities doped into the second source pattern SC2 may be the same as or different from a concentration of the impurities doped into the first source pattern SC1. The source structure SCL may correspond to the common source line CSL in FIG. 4. In addition, the second substrate 601 may also function as the common source line CSL in FIG. 4.

The memory block may include cell vertical patterns VS. An interior of the cell vertical patterns VS may be filled with an embedded insulating pattern 629. For example, the embedded insulating pattern 629 may have a single-film or multi-film structure of at least one of a silicon oxide film, a silicon nitride film and a silicon oxynitride film. A bit line pad BPD may be disposed on each of the cell vertical patterns VS. The bit line pad BPD may include polysilicon doped with impurities or a metal such as tungsten, aluminum, and copper. A gate insulating film GO may be interposed between the cell vertical patterns VS and the word lines 631 to 638. The cell vertical patterns VS, the embedded insulating pattern 629 and the gate insulating film GO may be collectively referred to as a channel CH.

First conductive lines BLL extending in the second direction Y and parallel to each other may be disposed on the second upper interlayer insulating film 608. The first conductive lines BLL may correspond to the bit lines BL of FIG. 3. In the bit line bonding area BLBA, the first contacts CT1 may penetrate the first and second upper interlayer insulating films 605 and 608 and connect the bit line pads BPD disposed on the vertical semiconductor patterns VS to the first conductive lines BLL, respectively.

An electrode interconnection CL may be disposed on the second upper interlayer insulating film 608. In the external pad bonding area PA, edge through vias ETHV may penetrate the first upper interlayer insulating film 605, flat insulating films 610 and 620, the second substrate 601 and the etch stop film 511 to contact each of the peripheral conductive pads 530b. As an example, one edge through via ETHV and one peripheral conductive pad 530b are illustrated in FIG. 16. The edge through vias ETHV may be connected to the electrode interconnection CL through a third contact CT3 disposed in the second upper interlayer insulating film 608. Accordingly, the word lines 631 to 638 may be connected to the peripheral circuit region PERI. A via insulating pattern SP2 may be interposed between the edge through via ETHV and the flat insulating films 610 and 620 and between the edge through via ETHV and the etch stop film 511.

The electrode interconnection CL may be covered with the third upper interlayer insulating film 609. An external terminal CP may be disposed on the third upper interlayer insulating film 609. A fourth contact CT4 may penetrate the third and second upper interlayer insulating films 609 and 608 to connect the external terminal CP to a substrate contact plug WC. A sidewall of the substrate contact plug WC may be covered with a contact insulating pattern SP3.

The non-volatile memory device 500 may provide a plurality of sub-blocks SB1 and SB2. A channel CH constituting each cell string may include a first sub-channel SCH1 and a second sub-channel SCH2. A region adjacent to the word lines 631 to 633 in the first sub-channel SCH1 may provide memory cells included in a first sub-block SB1. In addition, a region adjacent to the word lines 636 to 638 in the second sub-channel SCH2 may provide memory cells included in a second sub-block SB2. Furthermore, in the first and second subchannels SCH1 and SCH2, a region adjacent to one or more word lines 634 and 635 adjacent to a boundary of the first and second subchannels SCH1 and SCH2 in a vertical direction may provide a dummy cells.

Referring to FIG. 17, a non-volatile memory device 700 may have a flip chip structure. The flip chip structure may refer to a structure formed by manufacturing an upper chip including a cell region CELL on a first wafer, manufacturing a lower chip including a peripheral circuit region PERI on a second wafer, different from the first wafer, and then flipping and connecting the upper chip to the lower chip by a bonding process. For example, the bonding process may refer to a method of electrically connecting a bonding metal formed on an uppermost metal layer of the upper chip and a bonding metal formed on an uppermost metal layer of the lower chip. For example, when the bonding metals are formed of copper (Cu), the bonding method may be a Cu-Cu bonding method, and the bonding metals may also be formed of aluminum or tungsten.

Each of the peripheral circuit region PERI and the cell region CELL of the non-volatile memory device 700 may include an external pad bonding area PA, a word line bonding area WLBA and a bit line bonding area BLBA. The peripheral circuit region PERI may include a first substrate 710, an interlayer insulating film 715, a plurality of circuit elements 720a, 720b and 720c formed on the first substrate 710, first metal layers 730a, 730b and 730c respectively connected to the plurality of circuit elements 720a, 720b and 720c and second metal layers 740a, 740b and 740c formed on the first metal layers 730a, 730b and 730c. In an embodiment, the first metal layers 730a, 730b and 730c may be formed of tungsten having relatively high electrical resistivity, and the second metal layers 740a, 740b and 740c may be formed of copper having relatively low electrical resistivity.

In this specification, only the first metal layers 730a, 730b, 730c and the second metal layers 740a, 740b and 740c are illustrated and described, but not limited thereto, and at least one or more metal layers may be further formed on the second metal layers 740a, 740b and 740c. At least a portion of the one or more metal layers formed on the second metal layers 740a, 740b and 740c may be formed of aluminum or the like having a resistance lower than copper forming the second metal layers 740a, 740b and 740c.

The interlayer insulating film 715 may be disposed on the first substrate 710 to cover the plurality of circuit elements 720a, 720b and 720c, the first metal layers 730a, 730b and 730c, and the second metal layers 740a, 740b and 740c. The interlayer insulating film 715 may include an insulating material such as silicon oxide, silicon nitride or the like.

Lower bonding metals 771b and 772b may be formed on the second metal layer 740b in the word line bonding area WLBA. In the word line bonding area WLBA, the lower bonding metals 771b and 772b in the peripheral circuit region PERI may be electrically connected to upper bonding metals 871b and 872b of the cell region CELL by a bonding method. The lower bonding metals 771b and 772b and the upper bonding metals 871b and 872b may be formed of aluminum, copper, tungsten, or the like. The upper bonding metals 871b and 872b of the cell region CELL may be referred to as first metal pads, and the lower bonding metals 771b and 772b of the peripheral circuit region PERI may be referred to as second metal pads.

The cell region CELL may provide at least one memory block. The cell region CELL may include a second substrate 810 and a common source line 820. On the second substrate 810, a plurality of word lines 831 to 838 may be stacked in a direction (the Z-axis direction) perpendicular to an upper surface of the second substrate 810. String select lines and a ground select line may be arranged on and below word lines 831 to 838, and the plurality of word lines 831 to 838 may be disposed between the string select lines and the ground select line.

In the bit line bonding area BLBA, a channel structure CH may extend in a direction (the Z-axis direction), perpendicular to the upper surface of the second substrate 810, and penetrate the word lines 831 to 838, the string select lines, and the ground select line. The channel structure CH may include a data storage layer, a channel layer, an embedded insulating film and the like, and the channel layer may be electrically connected to a first metal layer 850c and a second metal layer 860c. For example, the first metal layer 850c may be a bit line contact, and the second metal layer 860c may be a bit line. In an embodiment, the bit line may extend in the first direction (the Y-axis direction), parallel to the upper surface of the second substrate 810.

In the embodiment illustrated in FIG. 17, an area in which the channel structure CH, the bit line 860c, and the like are disposed may be defined as the bit line bonding area BLBA. In the bit line bonding area BLBA, the bit line may be electrically connected to the circuit elements 720c providing a page buffer 893 in the peripheral circuit region PERI. For example, the bit line 860c may be connected to upper bonding metals 871c and 872c in the cell region CELL, and the upper bonding metals 871c and 872c may be connected to lower bonding metals 771c and 772c connected to the circuit elements 720c of the page buffer 893.

In the word line bonding area WLBA, the word lines 831 to 838 may extend in a second direction (an X-axis direction), parallel to the upper surface of the second substrate 810, and may be connected to a plurality of cell contact plugs 841 to 847 (i.e., 840). The word lines 831 to 838 and the contact plugs 840 may be connected to each other in pads provided by at least a portion of the plurality of word lines 831 to 838 extending in different lengths in the second direction (the X-axis direction). A first metal layer 850b and a second metal layer 860b may be sequentially connected to upper portions of the cell contact plugs 840 connected to the word lines 831 to 838. The cell contact plugs 840 may be connected to the peripheral circuit region PERI via the upper bonding metals 871b and 872b of the cell region CELL and the lower bonding metals 771b and 772b of the peripheral circuit region PERI in the word line bonding area WLBA.

The cell contact plugs 840 may be electrically connected to the circuit elements 720b providing a row decoder 894 in the peripheral circuit region PERI. In an embodiment, operating voltages of the circuit elements 720b of the row decoder 894 may be different from operating voltages of the circuit elements 720c providing the page buffer 893. For example, operating voltages of the circuit elements 720c providing the page buffer 893 may be greater than operating voltages of the circuit elements 720b forming the row decoder 894.

A common source line contact plug 880 may be disposed in the external pad bonding area PA. The common source line contact plug 880 may be formed of a conductive material such as a metal, a metal compound, polysilicon or the like, and may be electrically connected to the common source line 820. A first metal layer 850a and a second metal layer 860a may be sequentially stacked on an upper portion of the common source line contact plug 880. For example, an area in which the common source line contact plug 880, the first metal layer 850a, and the second metal layer 860a are disposed may be defined as the external pad bonding area PA.

Input/output pads 705 and 805 may be disposed in the external pad bonding area PA. Referring to FIG. 17, a lower insulating film 701 covering a lower surface of the first substrate 710 may be formed below the first substrate 710, and a first input/output pad 705 may be formed on the lower insulating film 701. The first input/output pad 705 may be connected to at least one of the plurality of circuit elements 720a, 720b and 720c disposed in the peripheral circuit region PERI through a first input/output contact plug 703, and may be separated from the first substrate 710 by the lower insulating film 701. In addition, a side insulating film may be disposed between the first input/output contact plug 703 and the first substrate 710 to electrically separate the first input/output contact plug 703 and the first substrate 710.

Referring to FIG. 17, an upper insulating film 801 covering the upper surface of the second substrate 810 may be formed on the second substrate 810, and a second input/output pad 805 may be disposed on the upper insulating film 801. The second input/output pad 805 may be connected to at least one of the plurality of circuit elements 720a, 720b and 720c disposed in the peripheral circuit region PERI through a second input/output contact plug 803.

In some embodiments, the second substrate 810 and the common source line 820 may not be disposed in a region in which the second input/output contact plug 803 is disposed. In addition, the second input/output pad 805 may not overlap the word lines 831 to 838 in a third direction (a Z-axis direction). Referring to FIG. 17, the second input/output contact plug 803 may be separated from the second substrate 810 in a direction, parallel to the upper surface of the second substrate 810, and may penetrate an interlayer insulating film 815 of the cell region CELL to be connected to the second input/output pad 805.

In some embodiments, the first input/output pad 705 and the second input/output pad 805 may be selectively formed. For example, the non-volatile memory device 700 may include only the first input/output pad 705 disposed on the first substrate 710, or may include only the second input/output pad 805 disposed on the second substrate 810. Alternatively, the non-volatile memory device 700 may include both the first input/output pad 705 and the second input/output pad 805.

A metal pattern provided on an uppermost metal layer may be provided as a dummy pattern or the uppermost metal layer may be absent, in each of the external pad bonding area PA and the bit line bonding area BLBA, respectively included in the cell region CELL and the peripheral circuit region PERI.

In the external pad bonding area PA, the non-volatile memory device 700 may include a lower metal pattern 773a, corresponding to an upper metal pattern 872a formed in an uppermost metal layer of the cell region CELL, and having the same shape as the upper metal pattern 872a of the cell region CELL, in an uppermost metal layer of the peripheral circuit region PERI. In the peripheral circuit region PERI, the lower metal pattern 773a formed in the uppermost metal layer of the peripheral circuit region PERI may not be connected to a separate contact. Similarly, in the external pad bonding area PA, an upper metal pattern, corresponding to the lower metal pattern formed in an uppermost metal layer of the peripheral circuit region PERI, and having the same shape as the lower metal pattern of the peripheral circuit region PERI, may be formed in an uppermost metal layer of the cell region CELL.

The lower bonding metals 771b and 772b may be formed on the second metal layer 740b in the word line bonding area WLBA. In the word line bonding area WLBA, the lower bonding metals 771b and 772b of the peripheral circuit region PERI may be electrically connected to the upper bonding metals 871b and 872b of the cell region CELL by a bonding method.

Furthermore, in the bit line bonding area BLBA, an upper metal pattern 892, corresponding to a lower metal pattern 752 formed in the uppermost metal layer of the peripheral circuit region PERI, and having the same shape as the lower metal pattern 752 of the peripheral circuit region PERI, may be formed in an uppermost metal layer of the cell region CELL. In an exemplary embodiment, a contact may not be formed on the upper metal pattern 892 formed in the uppermost metal layer of the cell region CELL.

In an exemplary embodiment, a reinforced metal pattern, corresponding to a metal pattern formed on the uppermost metal layer of one of the cell region CELL and the peripheral circuit region PERI, and having the same cross-sectional shape as a metal pattern formed on the uppermost metal layer of the other of the cell region CELL and the peripheral circuit region PERI, may be formed. A contact may not be formed in the reinforced metal pattern.

The non-volatile memory device 700 may provide a plurality of sub-blocks SB1 and SB2. A channel CH constituting each cell string may include a first sub-channel SCH1 and a second sub-channel SCH2. A region adjacent to the word lines 831 to 833 in the first sub-channel SCH1 may provide memory cells included in a first sub-block SB1. In addition, a region adjacent to the word lines 836 to 838 in the second sub-channel SCH2 may provide memory cells included in a second sub-block SB2. Furthermore, in the first and second subchannels SCH1 and SCH2, a region adjacent to one or more word lines 834 and 835 adjacent to a boundary of the first and second subchannels SCH1 and SCH2 in a vertical direction may provide dummy cells.

The dummy memory cells formed in a boundary layer may be implemented as a cell type or a transistor type. The cell type may refer to a type including a floating gate, such as a flash memory cell, and the transistor type may refer to a type in which the floating gate is omitted.

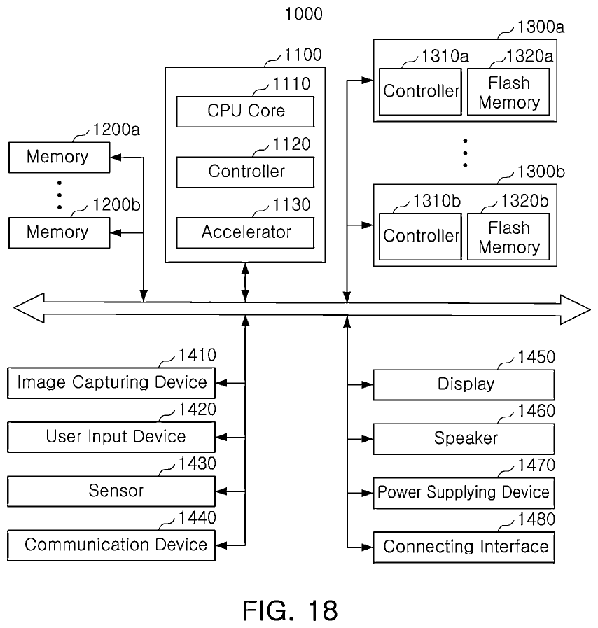

FIG. 18 is a diagram illustrating a system to which a storage device according to an embodiment of the present inventive concept may be applied.

FIG. 18 is a diagram illustrating a system 1000 to which a storage device according to an embodiment of the present inventive concept is applied. The system 1000 of FIG. 18 may be basically a mobile system, such as a mobile phone, a smartphone, a tablet personal computer (PC), a wearable device, a healthcare device, or an internet-of-things (IOT) device. The system 1000 of FIG. 18 is not necessarily limited to the mobile system, and may be for a vehicle such as a personal computer, a laptop computer, a server, a media player, an automotive device such as a navigation system, or the like.

Referring to FIG. 18, the system 1000 may include a main processor 1100, memories 1200a and 1200b and storage devices 1300a and 1300b and may further include at least one of an image capturing device 1410, a user input device 1420, a sensor 1430, a communication device 1440, a display 1450, a speaker 1460, a power supplying device 1470, or a connecting interface 1480.

The main processor 1100 may control an overall operation of the system 1000, and more specifically, operations of other components constituting the system 1000. The main processor 1100 may be implemented as a general-purpose processor, a dedicated processor, an application processor, or the like.

The main processor 1100 may include at least one CPU core 1110 and may further include a controller 1120 for controlling the memories 1200a and 1200b and/or the storage devices 1300a and 1300b. According to an embodiment, the main processor 1100 may further include an accelerator 1130 that may be a dedicated circuit for high-speed data operation such as artificial intelligence (AI) data operation. The accelerator 1130 may include a graphics processing unit (GPU), a neural processing unit (NPU), and/or a data processing unit (DPU), or the like, and may be implemented as a separate chip, physically independent from other components of the main processor 1100.

The memories 1200a and 1200b may be used as a main memory device of the system 1000, and may include volatile memories such as SRAM and/or DRAM, or the like, but may also include non-volatile memories such as flash memory, PRAM, and/or RRAM, or the like. The memories 1200a and 1200b may be implemented together with the main processor 1100 in the same package.

The storage devices 1300a and 1300b may function as non-volatile storage devices that store data regardless of whether power is supplied or not, and may have a relatively larger storage capacity, as compared to the memories 1200a and 1200b. The storage devices 1300a and 1300b may include storage controllers 1310a and 1310b and non-volatile memory (NVM) devices 1320a and 1320b for storing data under control of the storage controllers 1310a and 1310b. The non-volatile memory devices 1320a and 1320b may include a flash memory having a 2D (2-dimensional) structure or a 3D (3-dimensional) vertical NAND (V-NAND) structure, but may include other types of non-volatile memory such as PRAM and/or RRAM, or the like.

The storage devices 1300a and 1300b may be included in the system 1000 in a state physically separated from the main processor 1100, or may be implemented together with the main processor 1100 in the same package. In addition, the storage devices 1300a and 1300b may have a shape such as a solid state device (SSD) or a memory card, to be detachably coupled to other components of the system 1000 through an interface such as a connecting interface 1480 to be described later. Such storage devices 1300a and 1300b may be devices to which standard protocols such as a universal flash storage (UFS), an embedded multi-media card (eMMC), or a non-volatile memory express (NVMe) are applied, but the present inventive concept is not necessarily limited thereto.

According to an embodiment of the present inventive concept, the storage devices 1300a and 1300b may include non-volatile memory devices 1320a and 1320b, each of which includes memory blocks divided into a plurality of sub-blocks. The storage devices 1300a and 1300b may program original data into one or more first sub-blocks of a plurality of sub-blocks included in one memory block or a group of memory blocks in a first level cell mode, and program recovery data of the original data into one or more second sub-blocks of the plurality of sub-blocks in a second level cell mode having a bit density greater than that of the first level cell mode.

The image capturing device 1410 may capture a still image or a moving image, and may be a camera, a camcorder, and/or a webcam, or the like.

The user input device 1420 may receive various types of data of the system 1000, input by a user, and may be a touch pad, a keypad, a keyboard, a mouse, and/or a microphone, or the like.

The sensor 1430 may detect various types of physical quantities that may be acquired from the outside of the system 1000, and may convert the sensed physical quantities into electrical signals. Such a sensor 1430 may be a temperature sensor, a pressure sensor, an illuminance sensor, a position sensor, an acceleration sensor, a biosensor, and/or a gyroscope sensor, or the like.

The communication device 1440 may transmit and receive signals between other devices outside the system 1000 according to various communication protocols. Such a communication device 1440 may be implemented to include an antenna, a transceiver, and/or a modem, or the like.

The display 1450 and the speaker 1460 may function as output devices that respectively output visual information and auditory information to the user of the system 1000.

The power supplying device 1470 may appropriately convert power supplied from a battery (not illustrated) mounted in the system 1000 and/or an external power source, and may supply the switched power to each of the components of the system 1000.

The connecting interface 1480 may provide a connection between the system 1000 and an external device that may be connected to the system 1000 and may exchange data with the system 1000. The connecting interface 1480 may be implemented in various interface methods such as an advanced technology attachment (ATA), a serial ATA (SATA), an external SATA (e-SATA), a small computer small interface (SCSI), a serial attached SCSI (SAS), a peripheral component interconnection (PCI), a PCI express (PCIe), NVMe, IEEE 1394, a universal serial bus (USB), a secure digital (SD) card, a multi-media card (MMC), an eMMC, a UFS, an embedded universal flash storage (eUFS), a compact flash (CF) card interface, or the like.

A storage device according to an embodiment of the present inventive concept may program original data into a first sub-block of a plurality of sub-blocks disposed in a memory block in a vertical direction in a first level cell mode, and program mirrored data or parity data for recovering the original data into a second sub-block of the plurality of sub-blocks in a second level cell mode having a bit density greater than that of the first level cell mode. Accordingly, reliability of the original data stored in the memory block can be improved by using the mirrored data or parity data occupying a storage space less than that of the original data in the memory block.

While exemplary embodiments have been shown and described above, it will be apparent to those skilled in the art that modifications and variations could be made without departing from the scope of the present inventive concept as defined by the appended claims.

What is claimed is:

1. A storage device, comprising:
a non-volatile memory device comprising a plurality of memory blocks in which a plurality of cell strings are divided into a plurality of sub-blocks disposed in a vertical direction, wherein in each of the plurality of cell strings, a string select transistor, a plurality of memory cells and a ground select transistor are disposed in series, in the vertical direction, between a bit line and a source line; and
a storage controller configured to program original data into at least one first sub-block of the plurality of sub-blocks in a first level cell mode, and program recovery data for recovering the original data into at least one second sub-block of the plurality of sub-blocks in a second level cell mode having a bit density greater than that of the first level cell mode, in a first memory block of the plurality of memory blocks.

2. The storage device of claim 1, wherein the plurality of sub-blocks of the plurality of memory blocks have the same size, and
a ratio of the bit density of the second level cell mode to the bit density of the first level cell mode is inversely proportional to a ratio of a number of the second sub-block to a number of the first sub-block.

3. The storage device of claim 2, wherein the at least one first sub-block comprises three first sub-blocks, and the at least one second sub-block comprises one second sub-block, and
the first level cell mode is a single level cell (SLC) mode, and the second level cell mode is a triple level cell (TLC) mode.

4. The storage device of claim 2, wherein the at least one first sub-block comprises four first sub-blocks, and the at least one second sub-block comprises one second sub-block, and
the first level cell mode is a SLC mode, and the second level cell mode is a quadruple level cell (QLC) mode.

5. The storage device of claim 1, wherein the storage controller is configured to program two or more sets of recovery data into the at least one second sub-block.

6. The storage device of claim 5, wherein the plurality of sub-blocks in the plurality of memory blocks have the same size,
a number of the at least one first sub-block is the same as a number of the at least one second sub-block, in the first memory block, and
a number of sets of the recovery data programmed in the at least one second sub-block is determined based on a ratio of the bit density of the second level cell mode to the bit density of the first level cell mode.

7. The storage device of claim 6, wherein when the first level cell mode is an SLC mode and the second level cell mode is a TLC mode, the storage controller is configured to program three sets of the recovery data into the at least one second sub-block.

8. The storage device of claim 6, wherein when the first level cell mode is an SLC mode and the second level cell mode is a QLC mode, the storage controller is configured to program four sets of the recovery data into the at least one second sub-block.

9. The storage device of claim 1, wherein the recovery data is mirrored data from which the original data is copied, and
when a unit data that can be programmed into one physical page of the at least one second sub-block in the second level cell mode is programmed into the at least one first sub-block, the storage controller is configured to program mirrored data copying the unit data into the at least one second sub-block.

10. The storage device of claim 1, wherein the recovery data is mirrored data from which the original data is copied, and
the storage controller is configured to obtain the original data from the at least one first sub-block, and when an error correction of the obtained original data is not possible, to recover the original data by obtaining mirrored data from the at least one second sub-block.

11. The storage device of claim 10, wherein the storage controller is configured to determine a first relative address indicating a sequence of a first physical page, into which the original data is programmed, in the at least one first sub-block, determine a ratio of a space capacity of the original data to a space capacity of the mirrored data, calculate a second address indicating a sequence of a second physical page, into which the mirrored data is programmed, in the at least one second sub-block based on the first relative address and the ratio of the space capacity, and obtain the mirrored data from the second physical page using the second address.

12. The storage device of claim 1, wherein the recovery data is parity data of the original data, and
the storage controller is configured to obtain the original data from the at least one first sub-block, recover original data chunks associated with the original data from the at least one first sub-block when an error correction of the obtained original data is not possible, obtain parity data chunks associated with the original data from the at least one second sub-block, and recover the original data by using the original data chunks and the parity data chunks.

13. The storage device of claim 1, wherein the original data is metadata.

14. A storage device, comprising:
a non-volatile memory device comprising a plurality of memory blocks including a plurality of cell strings which is divided into a first sub-block and a second sub-block disposed in a vertical direction to the first sub-block, and having a size smaller than that of the first sub-block, wherein in each of the plurality of cell strings, a string select transistor, a plurality of memory cells and a ground select transistor are disposed in series, in the vertical direction, between a bit line and a source line; and
a storage controller configured to program original data into the first sub-block in a first level cell mode, and program mirrored data from which the original data is copied into the second sub-block in a second level cell mode having a bit density greater than that of the first level cell mode, in a first memory block of the plurality of memory blocks.

15. The storage device of claim 14, wherein a ratio of the bit density of the second level cell mode to the bit density of the first level cell mode is inversely proportional to a ratio of a size of the second sub-block to a size of the first sub-block.

16. The storage device of claim 15, wherein the first level cell mode is an SLC mode, and the second level cell mode is a TLC mode or a QLC mode.

17. A storage device, comprising:
a non-volatile memory device comprising a plurality of memory blocks in which a plurality of cell strings are divided into a plurality of sub-blocks disposed in a vertical direction, wherein in each of the plurality of cell strings, a string select transistor, a plurality of memory cells and a ground select transistor are disposed in series, in the vertical direction, between a bit line and a source line; and
a storage controller configured to program first original data into the plurality of sub-blocks in a first memory block of the plurality of memory blocks in a first level cell mode, program second original data into at least one first sub-block of the plurality of sub-blocks in a second memory block of the plurality of memory blocks in the first level cell mode, and program mirrored data from which the first original data and the second original data is copied into at least one second sub-block of the plurality of sub-blocks in the second memory block in a second level cell mode having a bit density greater than that of the first level cell mode.

18. The storage device of claim 17, wherein the plurality of sub-blocks of the plurality of memory blocks have the same size,
the first memory block comprises two sub-blocks,
the second memory block comprises one first sub-block and one second sub-block, and
the first level cell mode is an SLC mode, and the second level cell mode is a TLC mode.

19. The storage device of claim 17, wherein the storage controller is configured to obtain the original data from the plurality of sub-blocks of the first memory block or at least one first sub-block of the second memory block, obtain mirrored data from the at least one second sub-block when an error correction of the obtained original data is not possible, and recover the original data by using the mirrored data.

20. The storage device of claim 19, wherein addresses of the first memory blocks and the second memory blocks are consecutive, and
the storage controller is configured to determine a first relative address indicating a sequence of a first physical page, into which the original data is programmed, in the plurality of sub-blocks of the first memory block or at least one first sub-block of the second memory block, determine a ratio of a space capacity of the original data to a space capacity of the mirrored data, calculate a second address indicating a sequence of a second physical page, into which the mirrored data is programmed, in the at least one second sub-block based on the first relative address and the ratio of the space capacity, and obtain the mirrored data from the second physical page using the second address.
